(19) United States
(12) Patent Application Publication
(10) Pub. No.: US 2021/0402739 A1
(43) Pub. Date: Dec. 30, 2021

(54) FUNCTIONAL FILM AND METHOD FOR PRODUCING FUNCTIONAL FILM

(71) Applicant: FUJIFILM Corporation, Tokyo (JP)

(72) Inventor: Yoshihiko MOCHIZUKI, Minamiashigara-shi (JP)

(73) Assignee: FUJIFILM Corporation, Tokyo (JP)

(21) Appl. No.: 17/471,547

(22) Filed: Sep. 10, 2021

Related U.S. Application Data
(63) Continuation of application No. PCT/JP2020/013291, filed on Mar. 25, 2020.

(30) Foreign Application Priority Data
Mar. 27, 2019 (JP) 2019-059658

(51) Int. Cl. B32B 7/12; B32B 27/08; B32B 9/00; C23C 16/34

(52) U.S. Cl. CPC B32B 7/12; B32B 27/08; B32B 2307/732; C23C 16/345; B32B 2255/20; B32B 9/005

(57) ABSTRACT

It is an object to provide a functional film which does not require formation of a protective layer by laminating and applying a protective film, and sticking of the protective layer, and also has high moist heat resistance; and a method for producing the same. The object is accomplished by a configuration where the functional film includes a support, an inorganic layer, and a protective layer consisting of a resin film, in which the inorganic layer and the protective layer are directly joined to each other, and in a case where an intensity ratio obtained by dividing an intensity of a maximum peak B in a range of 2,900 to 3,000 cm⁻¹ by an intensity of a maximum peak A in a range of 2,800 to 2,900 cm⁻¹ in an infrared absorption spectrum is defined as B/A, the intensity ratio B/A in a surface of the protective layer on the inorganic layer side is 1.04 times or more the intensity ratio B/A in a surface of the protective layer on the opposite side.

### CROSS-REFERENCE TO RELATED APPLICATIONS

This application is a Continuation of PCT International Application No. PCT/JP2020/013291 filed on Mar. 25, 2020, which claims priority under 35 U.S.C. § 119(a) to Japanese Patent Application No. 2019-059658 filed on Mar. 27, 2019. Each of the above applications is hereby expressly incorporated by reference, in its entirety, into the present application.

### BACKGROUND OF THE INVENTION

### 1. Field of the Invention

The present invention relates to a functional film and a method for producing the functional film.

### 2. Description of the Related Art

Gas barrier films are used in order to protect elements and the like that are degraded by water and/or oxygen, or the like, such as solar cells, organic electroluminescence elements, and illumination devices using quantum dots.

In addition, a functional film having a laminated structure that includes an organic layer and an inorganic layer is known as a functional film having high gas barrier properties. The functional film having a laminated structure that includes an organic layer and an inorganic layer has a configuration in which at least one set of a combination of an inorganic layer and a base organic layer serving as a base layer (undercoat layer) of the inorganic layer is formed on a surface of a support.

In the functional film having a laminated structure that includes an organic layer and an inorganic layer, the inorganic layer mainly expresses a desired function such as gas barrier properties. Therefore, in a functional film having an inorganic layer, it is important that the inorganic layer is maintained in an appropriate state.

That is, in a case where the uppermost layer is an inorganic film, an inorganic layer may be broken by contact or the like, and a desired function such as gas barrier properties cannot be obtained. Therefore, in the functional film having an inorganic layer, a protective layer is formed on the uppermost layer in order to prevent the inorganic layer from being broken. As the protective layer, an organic layer formed by a coating method is generally used.

In addition, in the functional film having an inorganic layer, a process in which an inorganic layer is formed and then a protective film (lamination film) is laminated on the inorganic layer is also performed in order to protect the inorganic layer for a period until the protective layer is formed after the inorganic layer is formed.

For example, JP2011-207126A describes a method for producing a functional film such as a gas barrier film, including a step of continuously supplying a long support, a step of forming an inorganic film under reduced pressure, and a step of winding the support on a roll under reduced pressure while interposing a protective film that imparts a sliding property between the inorganic film and the support and that has a surface roughness Ra equal to or less than the thickness of the inorganic film.

JP2015-171798A describes a functional film including a first organic layer, an inorganic layer, and a second organic layer in this order, in which the second organic layer is a layer formed by curing a polymerizable composition that is applied directly onto a surface of the inorganic layer, the polymerizable composition includes a urethane-skeleton acrylate polymer, the urethane-skeleton acrylate polymer has a structure that includes an acrylic main chain and a side chain including a urethane polymer unit or a urethane oligomer unit, and the side chain has an acryloyl group at an end thereof.

### SUMMARY OF THE INVENTION

As shown in JP2011-207126A and JP2015-171798A, in a functional film having an inorganic layer as a layer expressing a main function, an inorganic film cannot be prevented from breaking and a high-performance functional film cannot be obtained unless a certain protective layers is formed on the inorganic film. That is, it is important that a surface of a functional film has a layer having a function of protecting an inorganic layer; a functional layer that enhances affinity for a product that uses the functional film; and the like.

In this respect, the functional films described in JP2011-207126A and JP2015-171798A are very functional and have excellent performance including a high ability of protecting an inorganic layer.

However, functional films in the related art, having an inorganic layer as a layer expressing a main function, also have a drawback that processes for producing the same are extremely complicated.

For example, in the case of producing a functional film having an inorganic layer by roll-to-roll, after the formation of an inorganic layer, a protective film is laminated on the inorganic layer and the laminate is wound into a roll shape in a film deposition apparatus for the inorganic layer. Subsequently, the roll is removed from the film deposition apparatus for the inorganic layer and loaded in a film deposition apparatus for an organic layer, the protective film is peeled, and then an organic layer serving as a protective layer is formed on the inorganic layer.

As described above, the functional film having an inorganic layer requires steps of, for example, laminating a protective film after the formation of an inorganic layer, attaching or detaching a roll from a film deposition apparatus for the inorganic layer to a film deposition apparatus for an organic layer, and peeling the protective film, whereby a production process for the functional film is extremely complicated.

In addition, depending on the type of the protective film and the state of the protective film after peeling from the inorganic layer, there may be cases where the protective film should be discarded, which is thus disadvantageous in terms of cost.

In addition, it is also known that in the functional film having an inorganic layer, a protective layer is formed on a surface of the inorganic layer by adhering a resin film serving as a protective layer of the inorganic layer with an adhesive.

However, in this case, the thickness of the functional film is increased by an amount of the adhesive, and in recent years, it is difficult to decrease the thickness of the functional film as required. In addition, the increase in the thickness of the functional film is also disadvantageous in terms of flexibility and optical characteristics.

Further, the adhesion of the protective film using an adhesive also requires a step of applying the adhesive onto a surface of the inorganic layer or a surface of the resin film. In particular, since the formation of the inorganic layer is generally performed in vacuum, the application of the adhesive onto the inorganic layer is a separate step, which causes an increase in cost and a complicated production step.

In addition, there are significant restrictions on the adhesion between the inorganic layer and the resin film using an adhesive. For example, the application of the adhesive to the inorganic layer has restrictions such as a limited heating temperature, a limited solvent that can be used, and the inorganic layer acting as a barrier to suppress the volatilization of the solvent.

Moreover, the adhesive often has insufficient heat resistance and moisture resistance, and thus, has a problem that the protective layer is peeled in a case where the adhesive is used for a long period of time under a high temperature and a high humidity.

An object of the present invention is to solve such a problem, and is thus to provide a functional film having an inorganic layer such as a gas barrier film, in which the inorganic layer can be suitably protected, formation of a protective layer by laminating and applying a protective film on the inorganic layer, and sticking of the protective layer by an adhesive are not required, and the functional film has high heat resistance and moisture resistance; and a method for producing the functional film.

In order to accomplish such an object, the present invention has the following configurations.

[1] A functional film comprising:

a support;

an inorganic layer; and

a protective layer consisting of a resin film,

in which the inorganic layer and the protective layer are directly joined to each other,

in a case where a maximum peak in a range of 2,800 to 2,900 cm⁻¹ is defined as a peak A and a maximum peak in a range of 2,900 to 3,000 cm⁻¹ is defined as a peak B in an infrared absorption spectrum, and an intensity ratio obtained by dividing an intensity of the peak B by an intensity of the peak A is defined as B/A,

the intensity ratio B/A in a surface of the protective layer on the inorganic layer side is 1.04 times or more the intensity ratio B/A in a surface of the protective layer on an opposite side to the inorganic layer.

[2] The functional film as described in [1],

in which the inorganic layer contains an inorganic compound containing silicon as a main component.

[3] The functional film as described in [2],

in which the inorganic layer contains any one of silicon nitride, silicon oxide, or silicon oxynitride as a main component.

[4] The functional film as described in any one of [1] to [3],

in which a thickness of the inorganic layer is 50 nm or less.

[5] The functional film as described in any one of [1] to [4],

in which the functional film has a base layer between the support and the inorganic layer.

[6] The functional film as described in any one of [1] to [5],

in which a peeling strength between the protective layer and the inorganic layer is 2.5 N/25 mm or more.

[7] The functional film as described in any one of [1] to [6],

in which the protective layer contains polyethylene as a main component.

[8] A method for producing a functional film, comprising:

an inorganic layer forming step of forming an inorganic layer on a support by a gas phase film deposition method under reduced pressure,

a treating step of plasma-treating one surface of a resin film under reduced pressure; and

a bonding step of making the inorganic layer and the plasma-treated surface of the resin film face each other while maintaining the reduced pressure to bond the inorganic layer to the resin film.

[9] The method for producing a functional film as described in [8],

in which in the bonding step, a temperature of the resin film at the time of bonding the inorganic layer to the resin film is 80° C. or lower.

[10] The method for producing a functional film as described in [8] or [9],

in which the formation of the inorganic layer in the inorganic layer forming step is performed by plasma CVD.

[11] The method for producing a functional film as described in any one of [8] to [10],

in which it is the inorganic layer that first comes into contact with the resin film after the formation of the inorganic layer in the inorganic layer forming step.

[12] The method for producing a functional film as described in any one of [8] to [11],

in which the support is a long support. and the inorganic layer forming step and the bonding step are performed while the long support is transported in a longitudinal direction.

[13] The method for producing a functional film as described in any one of [8] to [12],

in which the resin film is a long resin film, and the treating step is performed while the long resin film is transported in a longitudinal direction.

[14] The method for producing a functional film as described in any one of [8] to [13],

in which a base layer forming step of forming a base layer on a surface of the support is performed before the inorganic layer forming step.

According to the present invention, provided is a functional film having an inorganic layer such as a gas barrier film, in which the inorganic layer can be suitably protected, lamination of a protective film on the inorganic layer, formation of a protective layer by application, and adhesion of the protective layer by an adhesive are not required, and the functional film has high heat resistance and moisture resistance

### BRIEF DESCRIPTION OF THE DRAWINGS

FIG. 1 is a conceptual diagram showing an example of a functional film of the present invention.

FIG. 2 is a conceptual diagram showing another example of the functional film of the present invention.

FIG. 3 is a conceptual diagram of an example of an organic film deposition apparatus for producing a functional film.

FIG. 4 is a conceptual diagram of an example of an inorganic film deposition apparatus for producing a functional film.

### DESCRIPTION OF THE PREFERRED EMBODIMENTS

Hereinafter, embodiments of the functional film of the embodiment of the present invention and the method for producing a functional film will be described with reference to drawings.

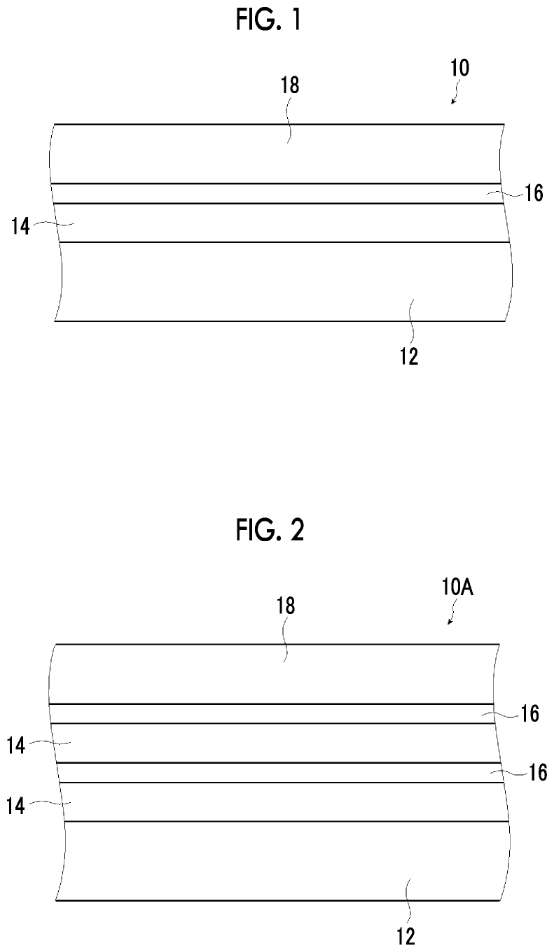

FIG. 1 conceptually shows an example of the functional film of the embodiment of the present invention.

FIG. 1 is a conceptual diagram of the functional film of the embodiment of the present invention, as viewed from a plane direction of the main surface. The main surface is a maximum area surface of a sheet-like object (a film or a plate-like object).

A functional film 10 shown in FIG. 1 is used as, for example, a gas barrier film, and is configured to have a support 12, a base layer 14, an inorganic layer 16, and a protective layer 18.

As will be described in detail later, in the functional film of the embodiment of the present invention, the protective layer 18 consists of a resin film, and the inorganic layer 16 and the protective layer 18 are directly joined to each other. In addition, in a case where a maximum peak in a range of 2,800 to 2,900 cm⁻¹ is defined as a peak A and a maximum peak in a range of 2,900 to 3,000 cm⁻¹ is defined as a peak B in an infrared absorption spectrum, and an intensity ratio obtained by dividing an intensity of the peak B by an intensity of the peak A is defined as B/A in the protective layer 18, the intensity ratio B/A in a surface of the protective layer on the inorganic layer side 16 side is 1.04 times or more the intensity ratio B/A in a surface of the protective layer on an opposite side to the inorganic layer 16.

In the following description, the support 12 side of the functional film 10 is also referred to as “lower”, and the protective layer 18 side is also referred to as “upper”.

The functional film 10 shown in FIG. 1 is a functional film having an inorganic layer 16 and a base layer 14 serving as a base for the inorganic layer 16, and having a laminated structure that includes an organic layer and an inorganic layer, mentioned above.

However, in the present invention, the base layer 14 is provided as a preferred aspect, and is not an essential configuration requirement in the functional film of the embodiment of the present invention. Accordingly, the functional film of the embodiment of the present invention may be configured to have the inorganic layer 16 on the support 12 and have the protective layer 18 on the inorganic layer 16.

In addition, the example shown in FIG. 1 has one set of a combination of the base layer 14 and the inorganic layer 16, but the present invention is not limited thereto. For example, the functional film of the embodiment of the present invention may have two sets of combinations of the base layer 14 and the inorganic layer 16, as in the functional film 10A conceptually shown in FIG. 2. Alternatively, the functional film of the embodiment of the present invention may have three or more sets of combinations of the base layer 14 and the inorganic layer 16.

Alternatively, the functional film of the embodiment of the present invention preferably has the base layer 14 on the support 12, may have the inorganic layer 16 on the base layer 14, may have the protective layer 18 on the inorganic layer 16, may have a second layer of the inorganic layer 16 on the protective layer 18, and may have the second layer of the protective layer 18 on the second layer of the inorganic layer 16. In addition, the functional film may have three or more set of combinations of the inorganic layer 16 and the protective layer 18.

That is, for the functional film of the embodiment of the present invention, various layer configurations are available as long as the functional film has a support 12 and one or more inorganic layers 16, and a protective layer 18 consisting of a resin film which will be described later is directly joined to the inorganic layer 16 that is the most distant from the support 12. In addition, basically, the larger the number of the inorganic layers 16, the more advantageous in terms of gas barrier properties.

However, it is preferable that the inorganic layer 16 is a single layer from the viewpoints that, for example, sufficient gas barrier properties can be ensured, the thickness of a functional film can be decreased, a functional film having good flexibility can be obtained, high productivity can be obtained, and a production step can be simplified. Above all, in particular, the functional film 10 shown in FIG. 1 having the base layer 14 on the support 12, an inorganic layer 16 on the base layer 14, and the protective layer 18 on the inorganic layer 16 is preferably exemplified.

The support 12 supports the base layer 14, the inorganic layer 16, and the protective layer 18.

As the support 12, various known sheet-like materials that are used as a support in various functional films such as the above-mentioned functional film having a laminated structure that includes an organic layer and an inorganic layer and various known gas barrier films are available.

The material of the support 12 is not limited, and various materials can be used as long as the base layer 14 or the inorganic layer 16 can be formed. Preferred examples of the material of the support 12 include various resin materials.

Examples of the material of the support 12 include polyethylene (PE), polyethylene naphthalate (PEN), polyamides (PA), polyethylene terephthalate (PET), polyvinyl chloride (PVC), polyvinyl alcohol (PVA), polyacrylonitrile (PAN), polyimides (PI), transparent polyimides, polymethyl methacrylate resins (PMMA), polycarbonates (PC), polyacrylates, polymethacrylates, polypropylene (PP), polystyrene (PS), acrylonitrile-butadiene-styrene copolymers (ABS), cycloolefin copolymers (COC), cycloolefin polymers (COP), triacetyl cellulose (TAC), and ethylene-vinyl alcohol copolymers (EVOH).

A thickness of the support 12 is not limited, and may be appropriately set in accordance with the use of the functional film 10, the material of the support 12, and the like.

The thickness of the support 12 is preferably 5 to 150 μm, and more preferably 10 to 100 μm from the viewpoints that, for example, the mechanical strength of the functional film 10 can be sufficiently secured, the functional film 10 having good flexibility can be obtained, a decrease in the weight and the thickness of the functional film 10 can be promoted, and the functional film 10 having good flexibility can be obtained.

In the functional film 10, the base layer 14 is formed on the support 12 (one surface).

The base layer 14 is, for example, a layer consisting of an organic compound obtained by polymerizing (crosslinking or curing) monomers, dimers, oligomers, or the like. As mentioned above, in the present invention, the base layer 14 is provided as a preferred aspect.

The base layer 14 serving as a lower layer of the inorganic layer 16 is a layer serving as a base that appropriately forms the inorganic layer 16.

The base layer 14 formed on a surface of the support 12 embeds irregularities on a surface of the support 12, and foreign matter and the like adhering to the surface to make the surface having the inorganic layer 16 formed thereon proper, which enables the inorganic layer 16 to be properly formed.

Furthermore, as mentioned above, the functional film of the embodiment of the present invention may have a plurality of sets of combinations of the inorganic layer 16 and the base layer 14. In this case, the base layer 14 serving as a second layer or any of subsequent layers is formed on the inorganic layer 16, but even with this configuration, the base layer 14 serving as a surface having the inorganic layer 16 formed thereon expresses the same action.

In particular, by placing such the base layer 14 on a surface of the support 12, it is possible to properly form the inorganic layer 16 that mainly expresses gas barrier properties.

The base layer 14 is formed by, for example, curing a composition for forming a base layer, which contains an organic compound (a monomer, a dimer, a trimer, an oligomer, a polymer, and the like). The composition for forming a base layer may include one organic compound or may include two or more organic compounds.

The base layer 14 contains, for example, a thermoplastic resin and an organosilicon compound. Examples of the thermoplastic resin include polyesters, (meth)acrylic resins, methacrylic acid-maleic acid copolymers, polystyrene, transparent fluororesins, polyimides, fluorinated polyimides, polyamides, polyamide-imides, polyetherimides, cellulose acylate, polyurethanes, polyether ether ketone, polycarbonates, alicyclic polyolefins, polyarylates, polyether sulfones, polysulfones, fluorene ring-modified polycarbonates, alicycle-modified polycarbonates, fluorene ring-modified polyesters, and acrylic compounds. Examples of the organosilicon compound include polysiloxane.

It is preferable that the base layer 14 includes a polymer of a radically curable compound and/or a cationically curable compound having an ether group from the viewpoints of an excellent strength and a glass transition temperature.

It is preferable that the base layer 14 contains a (meth)acrylic resin including a (meth)acrylate monomer or a polymer such as an oligomer as a main component from the viewpoint that the refractive index of the base layer 14 is decreased. By decreasing the refractive index of the base layer 14, the transparency is enhanced and the light transmittance is improved.

The base layer 14 more preferably includes a (meth)acrylic resin that contains, as a main component, a polymer derived from a monomer, a dimer, an oligomer, and the like of a bifunctional or higher functional (meth)acrylate, such as dipropylene glycol di(meth)acrylate (DPGDA), trimethylolpropane tri(meth)acrylate (TMPTA), and dipentaerythritol hexa(meth)acrylate (DPHA), and still more preferably includes a (meth)acrylic resin that contains, as a main component, a polymer derived from a monomer, a dimer, an oligomer, and the like of a trifunctional or higher functional (meth)acrylate. In addition, a plurality of these (meth)acrylic resins may be used.

The composition for forming a base layer preferably includes an organic solvent, a surfactant, a silane coupling agent, and the like, in addition to the organic compound.

In a case where a plurality of the base layers 14 are provided, that is, a case where a plurality of sets of combinations of the base layer 14 and the inorganic layer 16 are provided, the materials of the respective base layers 14 may be the same as or different from each other.

A thickness of the base layer 14 is not limited and can be appropriately set in accordance with the components included in the composition for forming a base layer, the support 12 used, and the like.

The thickness of the base layer 14 is preferably 0.1 to 5 μm, and more preferably 0.2 to 3 μm. By setting the thickness of the base layer 14 to 0.1 μm or more, for example, irregularities on a surface of the support 12, and foreign matter and the like adhering to the surface are embedded, and the surface of the base layer 14 can be planarized, and from this viewpoint, such the thickness is preferable. By setting the thickness of the base layer 14 to 5 μm or less, for example, cracks in the base layer 14 can be prevented, the flexibility of the functional film 10 can be enhanced, and the thickness and the weight of the functional film 10 can be decreased, and from these viewpoints, the thickness is preferable.

In a case where a plurality of base layers 14 are provided, that is, a case where a plurality of sets of combinations of the inorganic layer 16 and the base layer 14 are provided, the thicknesses of the respective base layers 14 may be the same as or different from each other.

The base layer 14 can be formed by a known method depending on the material.

For example, the base layer 14 can be formed by a coating method in which the above-mentioned composition for forming a base layer is applied to the support 12 and the composition for forming a base layer is dried. In the formation of the base layer 14 by the coating method, the dried composition for forming a base layer is further irradiated with ultraviolet rays, as needed, to polymerize (crosslink) the organic compounds in the composition for forming a base layer.

The base layer 14 is preferably formed by a roll-to-roll process. In the following description, “roll to roll” is also referred to as “R-to-R”.

As is well known, the R-to-R process is a production method in which a long sheet-like product is fed from a roll of a long sheet-like product and subjected to film fonnation while being transported in the longitudinal direction, and the sheet-like product after the film formation is wound into a roll shape. By using the R-to-R process, a high productivity and a production efficiency can be obtained.

In the functional film 10, the inorganic layer 16 is formed on (a surface of) the base layer 14. In the functional film 10, the inorganic layer 16 mainly expresses a desired function such as gas barrier properties.

The surface of the support 12 has regions where a film of an inorganic compound is not easily deposited, such as irregularities and shadows of foreign matter. By providing the base layer 14 and forming the inorganic layer 16 thereon, a region where the film of an inorganic compound is not easily deposited is covered. Therefore, the inorganic layer 16 can be formed, without a gap, on a surface having the inorganic layer 16 formed thereon.

A material of the inorganic layer 16 is not limited, and for example, various known inorganic compounds that are used for known gas barrier layers consisting of an inorganic compound expressing gas barrier properties can be used.

Examples of the material of the inorganic layer 16 include inorganic compounds, for example, metal oxides such as aluminum oxide, magnesium oxide, tantalum oxide, zirconium oxide, titanium oxide, and indium tin oxide (ITO); metal nitrides such as aluminum nitride; metal carbides such as aluminum carbide; oxides of silicon such as silicon oxide, silicon oxynitride, silicon oxycarbide, and silicon oxycarbonitride; nitrides of silicon such as silicon nitride and silicon carbonitride; carbides of silicon such as silicon carbide; hydrides thereof; mixtures of two or more thereof; and hydrogen-containing products thereof. In addition, mixtures of two or more of these inorganic compounds can also be used.

Among those, silicon nitride, silicon oxide, silicon oxynitride, aluminum oxide, and a mixture of two or more thereof are suitably used from the viewpoint that they have high transparency and can express excellent gas barrier properties. Among these, the compound including silicon is preferably used from the viewpoint that it can enhance the adhesiveness to the protective layer 18. Among the compounds including silicon, silicon nitride, silicon oxide, or silicon oxynitride is preferably used. Among these, silicon nitride is preferably used from the viewpoint that the adhesiveness to the protective layer 18 can be enhanced and excellent gas barrier properties can be expressed.

That is, the inorganic layer 16 preferably contains a compound having silicon as a main component, more preferably has any one of silicon nitride, silicon oxide, or silicon oxynitride as a main component, and still more preferably contains silicon nitride as a main component.

Furthermore, in the present invention, the main components in the support 12, the base layer 14, the inorganic layer 16, the protective layer 18, and the like are components included in the layer in the largest amount in terms of mass ratio. The main component is preferably a component included in the layer in an amount of more than 50% by mass, and more preferably a component included in the layer in an amount of more than 70% by mass.

A thickness of the inorganic layer 16 is not limited, and can be appropriately set depending on the material, such that desired gas barrier properties can be expressed.

The thickness of the inorganic layer 16 is preferably 5 to 150 nm, more preferably 8 to 75 nm, and still more preferably 10 to 50 nm.

By setting the thickness of the inorganic layer 16 to 5 nm or more, the inorganic layer 16 stably expressing sufficient gas barrier properties can be formed, and from this viewpoint, such the thickness is preferable. In addition, the inorganic layer 16 is generally brittle, and thus, in a case where the inorganic layer 16 is excessively thick, it can cause generation of breakage, cracks, peeling, or the like, whereas by setting the thickness of the inorganic layer 16 to 150 nm or less, the generation of breakage can be prevented.

In the inorganic layer 16, the intensity of a maximum peak in a range of 2,100 to 2,250 cm⁻¹ relative to the intensity of a maximum peak in a range of 800 to 1,100 cm⁻¹ in the infrared absorption spectrum is preferably 0.2 or less. That is, the inorganic layer 16 preferably satisfies “Maximum peak of 2,100 to 2,250 cm⁻¹)/(Maximum peak of 800 to 1,100 cm⁻¹)≥0.2”.

Furthermore, in the infrared absorption spectrum, the peak in a range of 800 to 1,100 cm⁻¹ is an Si—O or Si—N system peak. On the other hand, in the infrared absorption spectrum, the maximum peak in a range of 2,100 to 2,250 cm⁻¹ is the peak of Si—H.

Such a configuration can provide the inorganic layer 16 with a high density and a higher gas barrier properties, and further, a number of direct bonds between the inorganic layer 16 and the protective layer 18 as described later are formed to enhance the adhesiveness between the inorganic layer 16 and the protective layer 18.

As mentioned above, in a case where a plurality of inorganic layers 16 are provided, the thicknesses of the respective inorganic layers 16 may be the same as or different from each other.

In addition, in a case where a plurality of the inorganic layers 16 are provided, the materials of the inorganic layers 16 may be the same as or different from each other.

The inorganic layer 16 can be formed by a known method depending on the material.

Suitable examples of the method include various gas phase film deposition methods, for example, plasma CVDs such as capacitively coupled plasma (CCP)-CVD and inductively coupled plasma (ICP)-CVD, sputtering such as atomic layer deposition (ALD), magnetron sputtering, and reactive sputtering, and vacuum vapor deposition. Among these, the plasma CVDs are preferably used.

Further, the inorganic layer 16 is also preferably formed by an R-to-R process.

In the functional film 10, the protective layer 18 is formed on (a surface of) the inorganic layer 16.

In the functional film 10 of an embodiment of the present invention, the protective layer 18 is consisting of a resin film, and the inorganic layer 16 and the protective layer 18 are directly joined to each other without an adhesive (pressure sensitive adhesive).

In addition, in a case where a maximum peak in a range of 2,800 to 2,900 cm⁻¹ is defined as a peak A and a maximum peak in a range of 2,900 to 3,000 cm⁻¹ is defined as a peak B in an infrared absorption spectrum, and an intensity ratio obtained by dividing an intensity of the peak B by an intensity of the peak A is defined as B/A in the protective layer 18, the intensity ratio B/A in a surface of the protective layer on the inorganic layer side 16 side is 1.04 times or more the intensity ratio B/A in a surface of the protective layer on an opposite side to the inorganic layer 16.

Furthermore, in the following description, the infrared absorption spectrum is also referred to as an “IR spectrum”. In addition, in the following description, the intensity ratio B/A in a surface of the protective layer 18 on the inorganic layer 16 side is a “joint surface-side intensity ratio B/A”, and the intensity ratio B/A in a surface of the protective layer 18 on a side opposite to the inorganic layer 16 is also referred to as “surface-side intensity ratio B/A”.

By adopting this configuration of the functional film 10 of the present invention, a functional film which can sufficiently protect the inorganic layer 16, require neither lamination of a protective film after the formation of the inorganic layer 16 nor formation of a protective layer by coating for protecting the inorganic layer 16, and has high heat resistance and moisture resistance is realized.

As mentioned above, in a case of producing a functional film having an inorganic layer that expresses a desired function, the inorganic layer is formed, a protective film is then laminated on the inorganic layer, and the laminate is wound (in a vacuum chamber) in a film deposition apparatus for the inorganic layer. Subsequently, a roll obtained by winding the film having the inorganic layer formed thereon is loaded in a film deposition apparatus for a protective layer (organic layer), the protective film is peeled, and then an organic layer is formed as a protective layer that protects the inorganic layer, on the inorganic layer, by a coating method.

That is, with regard to a functional film having an inorganic layer in the related art, steps such as a step of laminating the protective film, a step of removing a roll from a film deposition apparatus for the inorganic layer, a step of loading the roll in a film deposition apparatus for a base layer, and a step of peeling the protective film are required after the formation of the inorganic layer in order to form a protective layer that protects the inorganic layer, and thus, a production process for the functional film is extremely complicated. In addition, the protective film may also need to be disposed, depending on the state of the protective film peeled from the inorganic layer.

As a method for avoiding such inconvenience, a method of forming an inorganic layer and then laminating a protective film such as a resin film as a protective layer, instead of the protective layer, on the inorganic layer can be considered.

However, in this method, an adhesive is required to stick the protective film to the inorganic layer with a sufficient adhesive force, and the thickness of the functional film increases by the amount of the adhesive. Therefore, with this configuration, it is difficult to attain a decrease in the thickness of the functional film, which has been required in recent years. In addition, the increase in the thickness of the functional film is also disadvantageous in terms of flexibility and optical characteristics. Further, a step of applying the adhesive onto a surface of the inorganic layer or a surface of the resin film is also required. In addition, the adhesion between the inorganic layer and the resin film by the adhesive has many restrictions such as temperature.

Moreover, the adhesive often has insufficient heat resistance and moisture resistance, and thus, has a problem that the protective layer is peeled in a case where the adhesive is used for a long period of time under a high temperature and a high humidity.

On the other hand, the functional film 10 of the embodiment of the present invention is used as the protective layer 18 by joining the resin film which has been laminated as a protective film on the inorganic layer directly to the inorganic layer 16 until the protective layer is formed after the formation of the inorganic layer in the related art. Accordingly, according to the present invention, the peeling of the protective film and formation of a protective layer are not required in the subsequent steps, and the protective film is not wasted.

Here, as is clear from the production of a functional film in the related art, even in a case where a protective film (resin film) is laminated on and bonded to a surface of the inorganic layer 16, the protective film can be easily peeled, and thus, a sufficient adhesive force which makes it possible to function as a protective layer cannot be obtained.

In contrast, in the functional film 10 of the embodiment of the present invention, the protective layer 18 consisting of a resin film has a joint surface-side intensity ratio B/A which is 1.04 times or more a surface-side intensity ratio B/A in the IR spectrum. By adopting such a configuration of the functional film 10 of the embodiment of the present invention, the protective layer 18 and the inorganic layer 16 can be directly and firmly joined to each other and adhered with a high adhesive force even without a use of an adhesive, and the protective layer 18 can be prevented from peeling for a long period of time even under a high temperature and a high humidity.

As mentioned above, the peak A is a maximum peak in a range 2,800 to 2,900 cm⁻¹ in the IR spectrum. On the other hand, the peak B is a maximum peak in a range of 2,900 to 3,000 cm⁻¹ in the IR spectrum.

In the IR spectrum, the peak A in a range of 2,800 to 2,900 cm⁻¹ is a peak of a methylene group (—CH₂—) and corresponds to a main chain moiety of the resin (polymer compound). On the other hand, in the IR spectrum, the peak B in a range of 2,900 to 3,000 cm⁻¹ is a peak of a methyl group (—CH₃) and corresponds to a terminal of a main chain of the resin.

In the IR spectrum, a large intensity ratio B/A indicates that the main chain of the resin is short and there are many terminals. This indicates that the resin has fewer bonds of molecules, that is, repeating units, and is soft. In addition, a description that there are many terminals of the main chain of the resin indicates that there are many bonds that can be bonded to other compounds, that is, an adhesive force to the adjacent layer can be enhanced.

That is, the description that the joint surface-side intensity ratio B/A is 1.04 times or more the surface-side intensity ratio B/A in the protective layer 18 indicates that the side of the inorganic layer 16 is softer, as compared with the side opposite to the inorganic layer 16, and there are many bonds with the inorganic layer 16 in the protective layer 18. That is, the description that the joint surface-side intensity ratio B/A is 1.04 times or more the surface-side intensity ratio B/A in the protective layer 18 indicates that the joint surface side with the inorganic layer 16 is softer, as compared with the surface side, and there are many bonds with the inorganic layer 16 in the protective layer 18.

Therefore, in the functional film 10 of the embodiment of the present invention, the protective layer 18 (resin film) suitably follows the fine irregularities of the hard inorganic layer 16 on the joint surface side with the inorganic layer 16, and can adhere with a high degree of adhesion without forming voids. That is, the contact area between the inorganic layer 16 and the protective layer 18 can be increased.

In addition, the protective layer 18 can be directly joined to the inorganic layer 16 with many bonds on the joint surface side with the inorganic layer 16. For example, the protective layer 18 can form a large number of Si—C bonds between Si of the inorganic layer and C of the protective layer 18 on the joint surface side with the inorganic layer 16.

As a result, in the functional film 10 of the embodiment of the present invention, the inorganic layer 16 and the protective layer 18 are directly joined to each other with a strong adhesive force, and a high adhesive force between the two layers can be obtained.

Moreover, the bond between the inorganic layer 16 and the protective layer 18 in the functional film 10 of the embodiment of the present invention is, for example, an Si—C bond in which Si of the inorganic layer 16 and C of the protective layer 18 are directly joined to each other. Therefore, the bond between the inorganic layer 16 and the protective layer 18 does not cause hydrolysis or the like due to moisture in any case, which is different from an Si—O—C bond or the like due to dehydration fusion using a silane coupling agent or the like. As a result, the functional film 10 of the embodiment of the present invention does not reduce a adhesive force between the inorganic layer 16 and the protective layer 18 even under a high temperature and a high humidity, and can prevent the protective layer 18 from peeling.

The functional film 10 of the embodiment of the present invention, having the inorganic layer 16 and the protective layer 18, can be produced by, for example, forming the inorganic layer 16 by a gas phase film deposition method under reduced pressure, and on the other hand, plasma-treating one surface of a resin film under reduced pressure, and making the inorganic layer 16 and the plasma-treated surface of the resin film face each other to bond the inorganic layer 16 and the resin film while maintaining the reduced pressure.

This production method will be described in detail later.

In the functional film 10 of the embodiment of the present invention, the joint surface-side intensity ratio B/A is 1.04 times or more the surface-side intensity ratio B/A in the protective layer 18.

The joint surface-side intensity ratio B/A that is less than 1.04 times or more the surface-side intensity ratio B/A causes inconvenience from the viewpoint that, for example, a sufficient adhesive force between the inorganic layer 16 and the protective layer 18 cannot be obtained, and sufficient durability under a high temperature and a high humidity cannot be obtained.

The joint surface-side intensity ratio B/A is preferably 1.07 times or more, and more preferably 1.1 times or more the surface-side intensity ratio B/A.

An upper limit of the magnitude of the joint surface-side intensity ratio B/A relative to the surface-side intensity ratio B/A is not limited. However, in a case where the intensity of the plasma treatment is too strong, there is a possibility that the surface of the resin film can be brittle while the adhesiveness to the inorganic layer 16 is lowered. In consideration of this viewpoint, the magnitude of the joint surface-side intensity ratio B/A relative to the surface-side intensity ratio B/A is preferably 1.5 times or less, and more preferably 1.4 times or less.

Furthermore, in the present invention, the IR spectra of a surface of the protective layer 18 on the inorganic layer 16 side and a surface of the protective layer 18 on a side opposite to the inorganic layer 16 may be measured by a known method.

As an example, a method of cutting a functional film in the thickness direction and measuring the IR spectrum of a cross-section by microscopic infrared spectrum analysis is exemplified.

Specifically, first, the functional film is cut diagonally in the thickness direction. With respect to this cross-section, the JR spectra of an edge surface of the protective layer 18 on the inorganic layer 16 side and an edge surface of the protective layer 18 on a side opposite to the inorganic layer 16, for example, in a range of 10×10 μm are measured, using an infrared microscope in reflection measurement (ATR) mode. As a result, the IR spectra of the surface of the protective layer 18 on the inorganic layer 16 side and the surface of the protective layer 18 on a side opposite to the inorganic layer 16 may be acquired.

Preferably, measurement of such an IR spectrum is performed at five points optionally selected on the edge surface on the inorganic layer 16 side and the edge surface on a side opposite to the inorganic layer 16. An average value of the intensities of the peak A and the peak B in the IR spectra at these five positions is taken as the values of the peak A and the peak B on the surface of the protective layer 18 on the inorganic layer 16 side and the surface of the protective layer 18 on a side opposite to the inorganic layer 16, respectively.

In the functional film 10 of the embodiment of the present invention, the protective layer 18, that is, the resin film serving as the protective layer 18 is not limited, and various known resin films can be used as long as they have a sufficient function as a protective layer of the inorganic layer 16.

Examples of the materials of the protective layer 18 include polyethylene (PE), an ethylene-vinyl acetate copolymer (EVA), polypropylene (PP), polyvinyl alcohol (PVA), polyvinyl chloride (PVC), polyethylene terephthalate (PET), polystyrene (PS), polymethyl methacrylate (PMMA), an ethylene-vinyl alcohol copolymer (EVOH), polyamide (PA), polyacrylonitrile (PAN), polyimide (PI), polycarbonate (PC), an acrylonitrile-butadiene-styrene copolymer (ABS), a cycloolefin copolymer (COC), a cycloolefin polymer (COP), and triacetylcellulose (TAC).

Among those, PE (PE film) is preferably used from the viewpoints of an adhesive force to the inorganic layer 16, high flexibility, low cost, availability as a heat sealing material, and the like. That is, in the present invention, it is preferable that the protective layer 18 contains PE as a main component.

Furthermore, as mentioned above, the resin film serving as the protective layer 18 is preferably soft as long as it can express a sufficient function as the protective layer 18, for example, from the viewpoint that a high adhesive force between the inorganic layer 16 and the protective layer 18 can be obtained.

The heat-resistance temperature of the protective layer 18 is not limited.

The heat-resistance temperature of the protective layer 18 is preferably 50° C. or higher, and more preferably 60° C. or higher from the viewpoint that sufficient heat resistance can be obtained, for example.

In addition, an upper limit of the heat-resistance temperature of the protective layer 18 is about 200° C. or lower in consideration of a fact that the protective layer 18 consists of a resin film.

Furthermore, in the present invention, the heat-resistance temperature of the protective layer 18 indicates a lower side of the melting point and the glass transition temperature of a material forming the protective layer 18.

The protective layer 18, that is, the resin film serving as the protective layer 18, is basically a single resin film that does not have an interface, a clear boundary, a joint surface, or the like in the thickness direction. Therefore, in a case where the resin film serving as the protective layer 18 is a single resin film that does not have an interface or the like, it may be a resin film in which a plurality of resins are joined to each other by a co-extrusion method (co-casting method) or the like.

However, in a case where the protective layer 18 is formed by a resin film in which different kinds of resins are joined to each other, such as a single resin film that does not have an interface or the like prepared by subjecting PE and EVA to a co-extrusion method, there is a possibility that inconveniences such as a warpage due to a difference in a coefficient of thermal expansion and peeling of the protective layer 18 due to the warpage may occur.

In consideration of this point, even in a case where the resin film that forms the protective layer 18 is a resin film in which a plurality of resins are joined to each other by a co-extrusion method, it is preferably a resin film formed of only one kind of resin, such as a resin film consisting of only PE and a resin film consisting of only EVA. Further, the resin film consisting of only one kind of resin may have a different average molecular weight in the thickness direction, may have a different molecular weight distribution in the thickness direction, may have a different crystallinity in the thickness direction, and may have a different hardness between one surface and the other surface.

As mentioned above, the resin film serving as the protective layer 18, which is soft, is advantageous in terms of the adhesive force between the inorganic layer 16 and the protective layer 18.

Therefore, in a case where the resin film serving as the protective layer 18 has a different hardness between one surface and the other surface, it is preferable that the soft side of the resin film faces the inorganic layer 16 to form the protective layer 18. The same applies to resin films produced by joining different kinds of resins.

In the functional film 10 of the embodiment of the present invention, a thickness of the protective layer 18 is not limited, and may be appropriately set in accordance with the protective layer 18, that is, a material of the resin film, durability required for the functional film 10, and the like. The thickness of the protective layer 18 is preferably 1 to 70 μm, more preferably 5 to 60 μm, and still more preferably 10 to 50 μm.

By setting the thickness of the protective layer 18 to 1 μm or more, the inorganic layer 16 can be suitably protected, and from this viewpoint, such the thickness is preferable.

By setting the thickness of the protective layer 18 to 70 μm or less, for example, a highly transparent functional film 10 can be obtained, and the functional film 10 can be prevented from being unnecessarily thick, and a functional film 10 having good flexibility can be obtained, and from this viewpoint, such the thickness is preferable.

In the functional film 10 of the embodiment of the present invention, it is basically preferable that the adhesive force between the inorganic layer 16 and the protective layer 18 is high.

Specifically, a peeling strength between the inorganic layer 16 and the protective layer 18 is preferably 2.5 N/25 mm or more, more preferably 3 N/25 mm or more, and still more preferably 3.5 N/25 mm or more.

Furthermore, the higher the peeling strength between the inorganic layer 16 and the protective layer 18, the more preferable it is, and although there is no upper limit in the peeling strength, the upper limit is generally 30 N/25 mm or less.

Moreover, in the functional film 10 of the embodiment of the present invention, the peeling strength between the inorganic layer 16 and the protective layer 18 may be measured in accordance with a 180° peel test of Japanese Industrial Standards (JIS) Z 0237:2009.

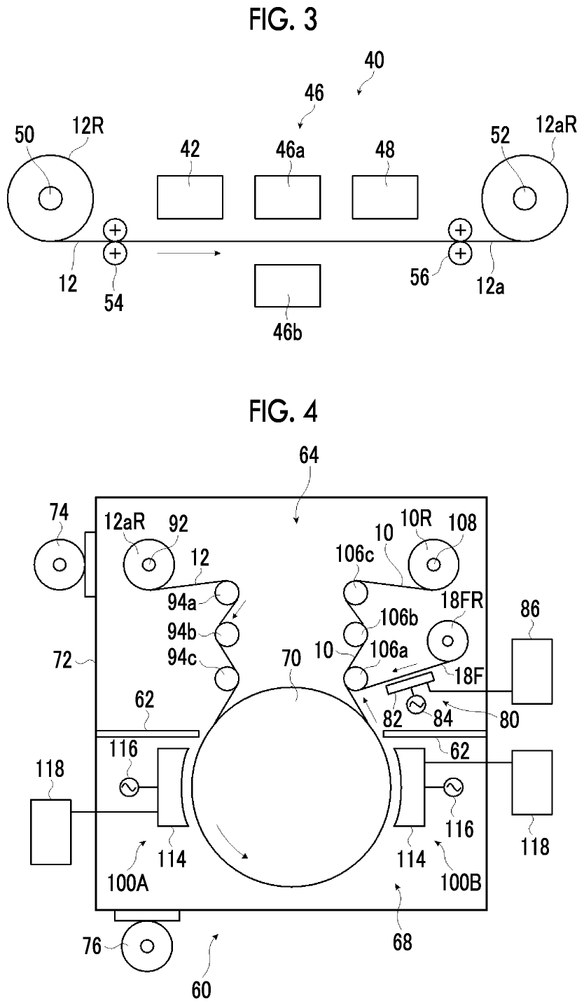

Hereinafter, an example of the method for producing the functional film 10 of the embodiment of the present invention will be described with reference to the conceptual diagrams of FIGS. 3 and 4.

The apparatus shown in FIG. 3 is an organic film deposition apparatus 40 that forms a base layer 14.

The organic film deposition apparatus 40 forms the base layer 14 by an R-to-R process. That is, in the organic film deposition apparatus 40, the above-mentioned composition for forming a base layer, which forms the base layer 14, is applied and dried while a long support 12 is transported in the longitudinal direction, and then an organic compound included in the composition for forming a base layer is polymerized (cured) by light irradiation, thereby forming the base layer 14.

As one example, the organic film deposition apparatus 40 in the illustrated example has a coating part 42, a drying part 46, a light irradiation part 48, a rotational shaft 50, a winding shaft 52, and transport roller pairs 54 and 56.

On the other hand, the apparatus shown in FIG. 4 is an inorganic film deposition apparatus 60 in which an inorganic layer 16 is formed, and a protective layer 18 is laminated on the inorganic layer 16. In the inorganic film deposition apparatus 60, a supply/winding chamber 64 and a film deposition chamber 68 are separated from each other by two partition walls 62 and a drum 70.

The inorganic film deposition apparatus 60 is also configured to form the inorganic layer 16 by an R-to-R process. That is, the inorganic film deposition apparatus 60 forms the inorganic layer 16 on a base layer 14 of a support 12 while a long support 12 having the base layer 14 formed thereon is transported in the longitudinal direction, and subsequently, a resin film 18F serving as the protective layer 18 is laminated on and adhered to a surface of the inorganic layer 16 to form the protective layer 18. Here, in the inorganic film deposition apparatus 60, a surface of the resin film 18F facing the inorganic layer 16 is subjected to a plasma treatment before laminating the resin film 18F on the inorganic layer 16.

In a case of producing the functional film 10, first, a support roll 12R formed by winding the long support 12 is loaded on a rotational shaft 50 of an organic film deposition apparatus 40.

In a case where the support roll 12R is loaded on the rotational shaft 50, the support 12 is drawn from the support roll 12R and is allowed to pass through the coating part 42, the drying part 46, and the light irradiation part 48 through the transport roller pair 54, and pass through a predetermined transport path leading to the winding shaft 52 through the transport roller pair 56.

The support 12 drawn from the support roll 12R is transported to the coating part 42 by the transport roller pair 54, and a composition for forming a base layer serving as a base layer 14 is applied onto a surface of the support.

The composition for forming a base layer serving as a base layer 14 includes an organic solvent, an organic compound (a monomer, a dimer, a trimer, an oligomer, a polymer, and the like) for forming a base layer 14, a surfactant, a silane coupling agent, and the like, as mentioned above.

In addition, various known methods such as a die coating method, a dip coating method, an air knife coating method, a curtain coating method, a roller coating method, a wire bar coating method, and a gravure coating method can be used for applying the composition for forming a base layer in the coating part 42.

The support 12 coated with the composition for forming a base layer serving as a base layer 14 is then heated by the drying part 46 to remove the organic solvent, and thus, dry the composition for forming a base layer.

The drying part 46 has a drying part 46a that performs drying by heating from the front surface side (composition for forming a base layer (side having the base layer 14 or the like formed thereon)) and a drying part 46b that performs drying by heating from the back surface side of the support 12, and performs the drying of the composition for forming a base layer from the both of the surface side and the back surface side

Heating in the drying part 46 may be performed by a known method for heating a sheet-like product. For example, the drying part 46a on the front surface side is a hot-air drying part, and the drying part 46b on the back surface side is a heat roller (a guide roller having a heating mechanism).

The support 12 in which the composition for forming a base layer serving as a base layer 14 is dried is then irradiated with ultraviolet rays or the like by the light irradiation part 48, and the organic compound is polymerized (crosslinked) and cured to form a base layer 14. Further, curing of the organic compound for forming the base layer 14 may be performed in an inert atmosphere such as a nitrogen atmosphere, as needed.

The support 12 having the base layer 14 formed thereon is transported by the transport roller pair 56 and wound into a roll shape by the winding shaft 52.

In a case where the formation of the base layer 14 having a predetermined length is finished, the support 12 is cut as needed and then taken as a support roll 12aR obtained by winding a support 12a having the base layer 14 thereon. The support roll 12aR is supplied to the inorganic film deposition apparatus 60 illustrated in FIG. 4, and subjected to formation of an inorganic layer 16 and formation of a protective layer 18.

Further, as described above, the base layer 14 is not an essential configuration requirement in the present invention. Accordingly, in the production method of an embodiment of the present invention, the formation of the base layer 14 is performed as a preferred aspect.

The inorganic film deposition apparatus 60 has a vacuum chamber 72. As mentioned above, the inside of the vacuum chamber 72 is separated into a supply/winding chamber 64 at the upper part in the drawing and a film deposition chamber 68 at the lower part in the drawing by two partition walls 62 and a drum 70.

The supply/winding chamber 64 has a vacuum exhausting unit 74. By driving the vacuum exhausting unit 74, a pressure within the supply/winding chamber 64 can be adjusted. The film deposition chamber 68 has a vacuum exhausting unit 76. By driving the vacuum exhausting unit 76, a pressure within the film deposition chamber 68 can be adjusted.

The supply/winding chamber 64 includes a plasma treating unit 80, a rotational shaft 92, pass rollers 94a to 94c, a supply roll 104, pass rollers 106a to 106c, and a winding shaft 108.

The film deposition chamber 68 has a first film deposition unit 100A and a second film deposition unit 100B.

In the inorganic film deposition apparatus 60, the inorganic layer 16 is formed on the base layer 14 while the long support 12 having the base layer 14 formed thereon is transported in the longitudinal direction, and the protective layer 18 is formed on the inorganic layer 16, thereby preparing a functional film 10.

First, the support roll 12aR formed by winding the support 12a having the base layer 14 formed thereon is loaded onto the rotational shaft 92. Subsequently, the support 12 drawn from the support roll 12aR is inserted into a predetermined transport path that extends to the winding shaft 108 via the pass rollers 94a to 94c, the drum 70, and the pass rollers 106a to 106c.

The support 12 drawn from the support roll 12aR is guided by the pass rollers 94a to 94c, thus wound around the drum 70, and transported in a predetermined path to form the inorganic layer 16 by the first film deposition unit 100A and/or the second film deposition unit 100B.

Furthermore, the drum 70 has a built-in temperature control unit. The support 12 is cooled or heated by the drum 70 as needed, and the inorganic layer 16 is formed by the first film deposition unit 100A and/or the second film deposition unit 100B.

Moreover, the drum 70 is configured to enable bias power to be supplied.

The film forming method in the first film deposition unit 100A and the second film deposition unit 100B is CCP-CVD as an example.

The first film deposition unit 100A and the second film deposition unit 100B have the same configuration, and have a shower electrode 114 forming an electrode pair with the drum 70, a high frequency power supply 116, and a gas supply unit 118.

The shower electrode 114 is a known shower electrode (shower plate) used for plasma CVD, which has an opening for supplying a raw material gas onto a surface facing the drum 70.

The high frequency power supply 116 supplies plasma excitation power to the shower electrode 114, and is a known high frequency power supply used for plasma CVD.

The gas supply unit 118 supplies the raw material gas to the shower electrode 114, and is a known gas supply unit used for plasma CVD. For example, in a case where silicon nitride is formed as the inorganic layer 16, examples of the raw material gas include a silane gas, an ammonia gas, and a hydrogen gas.

Moreover, a thickness of the inorganic layer 16 may be adjusted by a known method such as adjustment of plasma excitation power, adjustment of a film deposition time, that is, a transportation speed of the support 12, and adjustment of an amount of the raw material gas to be supplied.

A resin film 18F serving as the protective layer 18 is laminated on the support 12 having the inorganic layer 16 formed on the base layer 14, in the pass roller 106a immediately downstream of the drum 70. That is, the inorganic layer 16 and the resin film 18F serving as the protective layer 18 are laminated on and bonded to each other while maintaining the reduced pressure.

The resin film 18F is sent out from the resin film roll 18FR and transported to the pass roller 106a. Here, the plasma treating unit 80 is arranged in the transport path of the resin film 18F from the resin film roll 18FR to the pass roller 106a.

In the plasma treating unit 80, prior to lamination of the resin film 18F on the support 12 (inorganic layer 16), a surface of the resin film 18F facing the inorganic layer 16, that is, a surface of the protective layer 18 on the inorganic layer 16 side (joint surface) is subjected to a plasma treatment under reduced pressure.

In the production method of the embodiment of the present invention, such a plasma treatment is performed, the inorganic layer 16 and the resin film 18F are laminated on and adhered to each other while maintaining the reduced pressure, thereby preparing a functional film 10 having the inorganic layer 16 and the protective layer 18 which are firmly joined to each other as described above, and thus, the adhesive force is high.

That is, by subjecting a surface of the resin film 18F facing the inorganic layer 16 to a plasma treatment, a main chain of the resin is partially cut by plasma on the surface of the resin film 18F facing the inorganic layer 16. As a result, the surface of the resin film 18F on the inorganic layer 16 side is brought into a state where the main chain of the resin is short and there are many terminals, as mentioned above. As a result, the surface on the inorganic layer 16 side of the resin film 18F, that is, the protective layer 18, can have a joint surface-side intensity ratio B/A that is 1.04 times or more a surface-side intensity ratio B/A, as mentioned above. That is, the resin film 18F is subjected to a plasma treatment, and can thus be brought into a state where the surface of the protective layer 18 on the inorganic layer 16 side is softer and there are many bonds with the inorganic layer 16, as compared with the surface on a side opposite to the inorganic layer 16, as mentioned above.

On the other hand, the inorganic layer 16 is in a state where the reduced pressure is maintained after the formation of a film by plasma CVD, and thus, in a state where the surface activity is very high.

That is, in the inorganic film deposition apparatus 60, the resin film 18F which is soft and has many bonds and the inorganic layer 16 having a high surface activity are laminated on and bonded to each other.

As a result, as mentioned above, the resin film 18F that is soft suitably follows fine irregularities of the inorganic layer 16 to come into contact with a wide area, and is strongly joined and adhered through many bonds, for example, by the direct bonding of Si—C. As a result, the protective layer 18 is formed on the inorganic layer 16 with a strong adhesive force.

In the production method of the present invention, the resin film 18F that had been subjected to plasma treatment and the inorganic layer 16 are merely laminated on and adhered to each other. Accordingly, the produced functional film does not have any layer in which the component of the resin film 18F and the component of the inorganic layer 16 are mixed between the resin film 18F and the inorganic layer 16.

In the production method of the embodiment of the present invention, the plasma treatment of the resin film 18F may be performed by a known method.

In the inorganic film deposition apparatus 60 in the illustrated example, the plasma treating unit 80 includes a shower electrode 82, a high frequency power supply 84, and a gas supply unit 86. The shower electrode 82 is a known shower electrode used for a plasma treatment. The high frequency power supply 84 is a known high frequency power supply used for a plasma treatment. Further, the gas supply unit 86 supplies a plasma treatment gas to the shower electrode 82, and is a known gas supply unit used for a plasma treatment.

The intensity of the plasma treatment, and the like may be performed by a known method such as selection of a plasma treatment gas, adjustment of an amount of a plasma treatment gas to be supplied, adjustment of a pressure, adjustment of a plasma excitation power, or the like.

As the plasma treatment gas, various known gases used for a plasma treatment can be used. Preferred examples of the plasma treatment gas include an inert gas such as a nitrogen gas, a helium gas, and an argon gas, a hydrogen gas, an oxygen gas, and a mixed gas thereof.

The plasma excitation power may be appropriately set in accordance with the intensity of a plasma treatment, and the like. The plasma excitation power is preferably 0.1 to 5 kW, more preferably 0.3 to 4 kW, and still more preferably 0.4 to 3 kW.

The frequency of the plasma excitation power may also be appropriately set in accordance with a plasma excitation power, a plasma treatment gas used, and the like. The frequency of the plasma excitation power is preferably 0.01 to 3,000 MHz, more preferably 0.04 to 1,000 MHz, and still more preferably 0.08 to 500 MHz.

The plasma treatment pressure may also be appropriately set in accordance with a plasma excitation power, a plasma treatment gas used, and the like. The plasma treatment pressure is preferably 0.1 to 3,000 Pa, more preferably 1 to 2,000 Pa, and still more preferably 2 to 1,000 Pa.

In the production method of the embodiment of the present invention, the temperature of the resin film 18F in a case of being bonded to the inorganic layer 16 is preferably 80° C. or lower.

By setting the temperature of the resin film 18F in a case of being bonded to the inorganic layer 16 to 80° C. or lower, for example, a damage to the resin film 18F, that is, the protective layer 18 due to heat can be prevented, and the warpage of the functional film 10 due to a thermal stress during bonding and the peeling of the protective layer 18 can be prevented, and from this viewpoint, such the temperature is preferable.

The temperature of the resin film 18F in a case of being bonded to the inorganic layer 16 is more preferably 70° C. or lower, and still more preferably 60° C. or lower.

Furthermore, a lower limit of the temperature of the resin film 18F in a case of being bonded to the inorganic layer 16 is not limited, but in consideration of the activity of a surface of the resin film 18F, the flexibility of the resin film 18F in a case of being bonded, and the like, the lower limit is preferably 0° C. or higher.

In the production method of the embodiment of the present invention, it is preferably the resin film 18F that first comes into contact with the inorganic layer 16 after the inorganic layer 16 is formed.

As a result, a damage to the inorganic layer 16 due to a contact with a pass roller or the like can be prevented, and also the inorganic layer 16 and the resin film 18F are bonded to each other in a state where the activity of a surface of the inorganic layer 16 is sufficiently high, whereby an adhesive force between the inorganic layer 16 and the protective layer 18 can be increased.

The functional film 10 having the protective layer 18 formed thereon by laminating and bonding the resin film 18F is guided by the pass rollers 106a to 106c, transported to a winding shaft 108, and wound by the winding shaft 108, and thus, a functional film roll 10R around which the functional film 10 is wound can be obtained.

Thereafter, the vacuum chamber 72 is opened to atmosphere, and a purified dry air is introduced. Thereafter, the functional film roll 10R is then taken out from the vacuum chamber 72.

Furthermore, in a case where two or more sets of combinations of the base layer 14 and the inorganic layer 16 are formed, the same formation of the base layer 14 and the inorganic layer 16 may be repeated according to the number of combinations to be formed. In this case, in order to prevent a damage to the inorganic layer 16, it is preferable that except for the uppermost inorganic layer 16, the inorganic layer 16 is formed and then a protective film is laminated on the inorganic layer 16 and wound.

Although the functional film and the method for producing the functional film of the embodiments of the present invention have been described in detail above, the present invention is not limited to the aspects, and various improvements and modifications may be made without departing from the gist of the present invention.

For example, in the above-mentioned method for producing a functional film, all steps of forming the base layer 14, forming the inorganic layer 16, and laminating the resin film 18F, that is, forming the protective layer 18 are performed by an R-to-R process, as a preferred aspect. However, the present invention is not limited thereto, and at least one step may be performed in a batch method after cutting the film or all the steps may be performed in a batch method for a cut sheet.

### EXAMPLES

Hereinbelow, the present invention will be described in more detail with reference to Examples. The present invention is not limited to specific examples shown below.

### Example 1

<Support>

A PET film (manufactured by Toyobo Co., Ltd., COSMOSHINE A4300) having a width of 1,000 mm and a thickness of 100 μm was used as a support.

<Resin Film as Protective Layer>

As a resin film serving as a protective layer, a PE film A ((PE-A) manufactured by Sun A. Kaken Company, Limited, PAC-2A-30T) having a thickness of 30 μm was prepared.

<Formation of Base Layer>

TMPTA (manufactured by Daicel Allnex Ltd.) and a photopolymerization initiator (manufactured by Lamberti S.p.A., ESACURE KTO 46) were prepared and weighed such that a mass ratio of the TMPTA to the photopolymerization initiator was 95:5, and these were dissolved in methyl ethyl ketone (MEK) to reach a concentration of solid contents of 15% by mass, thereby preparing a composition for forming a base layer, which was intended to form a base layer.

As shown in FIG. 3, the prepared composition for forming a base layer was charged into a coating part of an organic film deposition apparatus having the coating part, a drying part, and a light irradiation part, and forming a base layer by a coating method through an R-to-R process.

In addition, a support roll formed by winding a long support into a roll shape was loaded at a predetermined position, and the support taken out from the support roll was inserted into a predetermined transport path.

In the organic film deposition apparatus, while the support was transported in the longitudinal direction, the composition for forming a base layer was applied in the coating part, and the composition for forming a base layer was dried in the drying part. A die coater was used in the coating part. The heating temperature in the drying part was 50° C. and the passage time in the drying part was 3 minutes.

Next, in the light irradiation part, the composition for forming a base layer was cured by irradiating the dried composition for forming a base layer with ultraviolet rays (an integrated irradiation amount of about 600 mJ/cm²) to form a base layer. Thereafter, the support having the base layer formed thereon was wound into a roll shape by the winding shaft.

The thickness of the formed base layer was 2 μm.

<Formation of Inorganic Layer and Protective Layer>

An inorganic film deposition apparatus as shown in FIG. 4 was used to form an inorganic layer and a protective layer. As mentioned above, this inorganic film deposition apparatus has a pass roller group, a drum, a first film deposition unit and a second film deposition unit, a pass roller group, and a plasma treating unit, and forms an inorganic layer by CCP-CVD through an R-to-R process, and a resin film which has been subjected to a plasma treatment is laminated on a support with the most upstream pass roller after the formation of the inorganic layer.

A support roll around which a support having a base layer formed thereon had been wound was loaded at a predetermined position of the inorganic film deposition apparatus. Subsequently, the support (the support that formed the base layer) taken out from the support roll was inserted into a predetermined transport path extending to a winding shaft via the pass roller, the drum, and the pass roller.

On the other hand, a resin film roll wound with a long PE film A (PE-A) serving as a protective layer was loaded at a predetermined position in the inorganic film deposition apparatus such that it was laminated on the inorganic layer in the most upstream pass roller after the formation of the inorganic layer.

A silicon nitride layer was formed as an inorganic layer on the base layer while the support taken out from the support roll was transported in the longitudinal direction.

Thereafter, the PE film A in which a surface on the inorganic layer side had been subjected to a plasma treatment was laminated on and bonded to the support having the inorganic layer formed thereon to form a protective layer.

In this manner, a functional film as shown in FIG. 1, having a base layer, an inorganic layer, and a protective layer on a support, was prepared. The prepared functional film was wound around the winding shaft.

Both the first film deposition unit and the second film deposition unit were used for forming the inorganic layer (silicon nitride layer). For the both, film deposition was performed under the same conditions.

As the raw material gas, a silane gas, an ammonia gas, and a hydrogen gas were used.

As an amount of the raw material gas to be supplied, the amounts of the silane gas, the ammonia gas, and the hydrogen gas supplied were 100 sccm, 250 sccm, and 500 sccm, respectively. The plasma excitation power was 1 kW and the frequency of the plasma excitation power was 13.56 MHz.

A bias power of 0.5 kW with a frequency of 0.4 MHz was supplied to the drum. In addition, the temperature of the drum was controlled to 60° C. by a cooling unit.

The transportation speed of the support was 10 m/min. The film formation pressure was 50 Pa.

The thickness of the inorganic layer was 30 nm.

In the plasma treatment of the PE film A by the plasma treating unit, the plasma excitation charge was 0.5 kW and the frequency of the plasma excitation power was 0.1 MHz.

As the plasma treatment gas, a mixed gas of an argon gas and a hydrogen gas was used. As an amount of the plasma treatment gas to be supplied, the amount of the argon gas to be supplied was 1,000 sccm and the amount of the hydrogen gas supplied was 100 sccm. The plasma treatment pressure was 10 Pa.

### Comparative Example 1

A functional film was prepared in the same manner as in Example 1, except that the PE film A serving as a protective layer was not subjected to a plasma treatment.

### Comparative Example 2

A PE film A which had not been subjected to a plasma treatment was laminated on a support having an inorganic layer formed thereon as a protective film to prepare a functional film having no protective layer.

Thereafter, the functional film was taken out from the inorganic film deposition apparatus and the PE film A as a protective film was peeled. Subsequently, a urethane-based adhesive was applied to the inorganic layer to a thickness of 5 μm, and the PE film A was adhered thereto as a protective layer to prepare a functional film.

### Comparative Example 3

As a resin film serving as a protective layer, a PE film B ((PE-B) manufactured by Mitsui Chemicals Tohcello, Inc., T500) having a thickness of 60 μm was prepared. This PE film B is a self-pressure sensitive adhesive film.

A functional film was prepared in the same manner as in Example 1, except that the PE film B was used instead of the PE film A, and the PE film B was not subjected to a plasma treatment.

### Example 2

A functional film was prepared in the same manner as in Example 1, except that in the formation of the inorganic layer (silicon nitride layer), as an amount of the raw material gas to supplied, the amounts of the silane gas, the ammonia gas, and the hydrogen gas supplied were 150 sccm, 375 sccm, and 500 sccm, respectively, and the plasma excitation power was 1.5 kW.

The thickness of the inorganic layer was 47 nm.

### Example 3

A functional film was prepared in the same manner as in Example 1, except that in the formation of the inorganic layer (silicon nitride layer), as an amount of the raw material gas to be supplied, the amounts of the silane gas, the ammonia gas, and the hydrogen gas supplied were 20 sccm, 50 sccm, and 500 sccm, respectively, and the plasma excitation power was 0.2 kW.

The thickness of the inorganic layer was 5 nm.

### Example 4

A functional film was prepared in the same manner as in Example 1, except that in the formation of the inorganic layer (silicon nitride layer), as an amount of the raw material gas to be supplied, the amounts of the silane gas, the ammonia gas, and the hydrogen gas supplied were 200 sccm, 500 sccm, and 500 sccm, respectively, and the plasma excitation power was 2 kW.

The thickness of the inorganic layer was 61 nm.

### Example 5

A functional film was prepared in the same manner as in Example 1, except that an inorganic layer (silicon nitride layer) was directly formed on a support while not forming a base layer.

### Example 6

A functional film was prepared in the same manner as in Example 1, except that the plasma excitation power was changed to 0.3 kW in the plasma treatment of the PE film A serving as the protective layer.

### Example 7

As a resin film serving as a protective layer, a PE film C ((PE-CB) manufactured by Mitsui Chemicals Tohcello, Inc., FC-D) having a thickness of 30 μm was prepared.

A functional film was prepared in the same manner as in Example 1, except that the PE film C was used instead of the PE film A.

### Example 8

As a resin film serving as a protective layer, an EVA film (LV342 manufactured by Mitsubishi Chemical Corporation) having a thickness of 30 μm was prepared.

A functional film was prepared in the same manner as in Example 1, except that the EVA film was used instead of the PE film A.

### Example 9

A functional film was prepared in the same manner as in Example 1, except that the inorganic layer was changed to a silicon oxide film.

A hexamethyldisiloxane (HMDSO) gas and an oxygen gas were used as the raw material gas. As an amount of the raw material gas to be supplied, the amounts of the HMDSO gas and the oxygen gas supplied were 100 sccm and 500 sccm, respectively, and the plasma excitation power was 1 kW.

### Example 10

A functional film was prepared in the same manner as in Example 1, except that the inorganic layer was changed to a silicon oxynitride film.

As the raw material gas, an HMDSO gas and a nitrous oxide (N₂O) gas were used. As an amount of the raw material gas to be supplied, the amounts of the HMDSO gas and the nitrous oxide gas supplied were 100 sccm and 200 sccm, respectively, and the plasma excitation power was 1 kW.

[Measurement of IR Spectrum]

The prepared functional film was obliquely cut at 10° using an inclined cutting machine to form an oblique cross-section in the thickness direction.

For this cross-section, the IR spectrum of an edge surface on the inorganic layer side and the edge surface on a side opposite to the inorganic layer, of the protective layer, was measured by a single reflection type ATR, using an infrared microscope IRT-5200 manufactured by JASCO Corporation. Ge was used as a material for the ATR prism. The measurement area was 10×10 μm.

As a result, the peak A which is a maximum peak in a range of 2,800 to 2,900 cm⁻¹ and the peak B which is a maximum peak in a range of 2,900 to 3,000 cm⁻¹ in the IR spectrum on a surface of the protective layer on the inorganic layer side (joint surface side) and a surface of the protective layer on an opposite side to the inorganic layer (surface side) were measured.

Furthermore, measurement of the IR spectrum was performed at five points optionally selected on an edge surface of the protective layer on the inorganic layer side and an edge surface of the protective layer on a side opposite to the inorganic layer. Then, an average value of the intensities of the peak A and the peak B at the five points was calculated, and this average value was taken as the values of the peak A and the peak B on the surface of the protective layer on the inorganic layer side and the surface of the protective layer on a side opposite to the inorganic layer, respectively.

From the measurement results, the magnitudes of the surface-side intensity ratio B/A (surface-side B/A), the joint surface-side intensity ratio B/A (joint surface-side B/A), and the joint surface-side intensity ratio B/A relative to the surface-side intensity ratio B/A were calculated.

Furthermore, the magnitudes of the joint surface-side intensity ratio B/A relative to the surface-side intensity ratio B/A was calculated by dividing [Joint surface-side intensity ratio B/A] by [surface-side intensity ratio B/A], and in the table, it is described as “Intensity ratio of joint surface to surface”.

[Evaluation]

A total light transmittance, the adhesiveness, and the gas barrier performance of the prepared functional film were evaluated.

<Total Light Transmittance>

With respect to the prepared functional film, the total light transmittance [%] was measured using NDH-7000 manufactured by Nippon Denshoku Industries Co., Ltd. in accordance with JIS K 7361-1 (1996).

<Adhesiveness>

As a test on the adhesiveness of the protective layer, a cross-cut peel test and a 180° peel test were performed.

<<180° Peel Test>>

A peeling strength (N/25 mm) was measured in accordance with the 180° peel test of JS Z 0237: 2009.

<<Cross-Cut Peel Test>>

A cross-cut peel test was performed in accordance with JIS K5600-5-6 (1999).

Cuts were formed on the protective layer on a surface of the functional film at an angle of 90° with respect to the film surface with an interval of 1 mm, using a cutter knife, to create a grid constituted by 100 squares having a side of 1 mm. A Mylar tape (manufactured by Nitto Denko Corporation, polyester tape, No. 31B) having a width of 2 cm was applied onto the surface and then peeled.

The adhesiveness was evaluated on the basis of the number of squares where the protective layer (resin film) remained (maximum: 100).

<Gas Barrier Properties>

A water vapor transmission rate (WVTR) [g/(m²·day)] of the prepared functional film was measured under the conditions of a temperature of 25° C. and a relative humidity of 50% RH by a calcium corrosion method (the method described in JP2005-283561A).

Furthermore, the 180° peel test, the cross-cut peel test, and measurement of gas barrier properties were performed under both of (a high temperature and a high humidity) by leaving the films to stand for 500 hours immediately after the preparation of the functional film (initial stage) and in an environment of a temperature of 85° C. and a relative humidity of 85% RH.

The results are shown in Table 1 below.

TABLE 1

| | | | Protective layer | | | | | |
|---|---|---|---|---|---|---|---|---|
| | | | | | IR spectrum | | | |
| | | | | | | | Intensity | Total |
| | Inorganic layer | | | Plasma | Joint | | ratio of | light |
| | | Thick- | | excitation | surface- | Surface- | joint | trans- |
| | | ness | Resin | power | side | side | surface to | mittance |
| | Material | [nm] | film | [kW] | B/A | B/A | surface | [%] |
| Example 1 | SiN | 30 | PE-A | 0.5 | 1.62 | 1.38 | 1.17 times | 85 |
| Comparative | SiN | 30 | PE-A | — | 1.40 | 1.38 | 1.01 times | 85 |
| Example 1 | | | | | | | | |
| Comparative | SiN | 30 | PE-A | — | 1.40 | 1.38 | 1.01 times | 79 |
| Example 2 | | | | | | | | |
| Comparative | SiN | 30 | PE-B | — | 1.51 | 1.50 | 1.01 times | 78 |
| Example 3 | | | | | | | | |
| Example 2 | SiN | 47 | PE-A | 0.5 | 1.62 | 1.38 | 1.17 times | 83 |
| Example 3 | SiN | 5 | PE-A | 0.5 | 1.62 | 1.38 | 1.17 times | 89 |
| Example 4 | SiN | 61 | PE-A | 0.5 | 1.62 | 1.38 | 1.17 times | 80 |
| Example 5 | SiN | 30 | PE-A | 0.5 | 1.62 | 1.38 | 1.17 times | 87 |
| Example 6 | SiN | 30 | PE-A | 0.3 | 1.43 | 1.37 | 1.04 times | 86 |
| Example 7 | SiN | 30 | PE-C | 0.5 | 1.51 | 1.41 | 1.07 times | 85 |
| Example 8 | SiN | 30 | EVA | 0.5 | 1.87 | 1.58 | 1.18 times | 86 |
| Example 9 | SiO₂ | 25 | PE-A | 0.5 | 1.62 | 1.38 | 1.17 times | 88 |
| Example 10 | SiON | 29 | PE-A | 0.5 | 1.62 | 1.38 | 1.17 times | 87 |
| | | | Adhesiveness | | | | Gas barrier properties | |
| | | | 180° peel test | | Cross-cut | | [g/(m² · day)] | |
| | | | | High | | High | | High |
| | | | | temperature | | temperature | | temperature |
| | | | Initial | and high | Initial | and high | Initial | and high |
| | | | stage | humidity | stage | humidity | stage | humidity |
| | | Example 1 | 5.1 | 5.1 | 100 | 100 | 2 × 10⁻⁵ | 2.1 × 10⁻⁵ |
| | | Comparative | 0.03 | 0.02 | 0 | 0 | 2 × 10⁻⁵ | 1 × 10⁻² |
| | | Example 1 | | | | | | |
| | | Comparative | 3.5 | 0.5 | 100 | 5 | 2 × 10⁻⁵ | 6 × 10⁻³ |
| | | Example 2 | | | | | | |
| | | Comparative | 2.8 | 0.3 | 81 | 2 | 2 × 10⁻⁵ | 8 × 10⁻³ |
| | | Example 3 | | | | | | |
| | | Example 2 | 4.7 | 4.5 | 100 | 100 | 1.8 × 10⁻⁵ | 2 × 10⁻⁵ |
| | | Example 3 | 6.2 | 6.2 | 100 | 100 | 3 × 10⁻⁵ | 3.1 × 10⁻⁵ |
| | | Example 4 | 5.5 | 5 | 100 | 99 | 1.8 × 10⁻⁵ | 2.4 × 10⁻⁵ |
| | | Example 5 | 3 | 2.8 | 100 | 100 | 1 × 10⁻⁴ | 1.1 × 10⁻⁴ |
| | | Example 6 | 3.6 | 3.6 | 100 | 100 | 2 × 10⁻⁵ | 2.1 × 10⁻⁵ |
| | | Example 7 | 3.8 | 3.8 | 100 | 100 | 2.2 × 10⁻⁵ | 2.3 × 10⁻⁵ |
| | | Example 8 | 8.9 | 8.8 | 100 | 100 | 1.9 × 10⁻⁵ | 2 × 10⁻⁶ |
| | | Example 9 | 4 | 4 | 100 | 100 | 7 × 10⁻⁵ | 7.2 × 10⁻⁵ |
| | | Example 10 | 4.1 | 4 | 100 | 100 | 5 × 10⁻⁵ | 5.2 × 10⁻⁵ |

The plasma excitation power is an excitation power in a plasma treatment of a resin film.
In Comparative Example 2, the protective layer is formed by adherence of the resin film by an adhesive, the resin film PE-B of Comparative Example 3 is self-pressure sensitive adhesive, and in the evaluations of the adhesiveness, a unit of the peel is [N/25 mm] and the cross-cut is the number of residual squares.

As shown in Table 1, the functional films of the embodiment of the present invention in which a resin film is directly joined as a protective layer and the IR spectra of the surfaces on the inorganic layer side and an opposite side thereto of the protective layer fall within a predetermined range all have good gas barrier properties and adhesiveness of the protective layer. In addition, since the protective layer has high adhesiveness, there are small decreases in the adhesiveness and the gas barrier properties after a long-term exposure to a high temperature and a high humidity environment and after a ball drop test.

Moreover, as shown in Examples 1 and 5, higher adhesiveness and gas barrier performance can be obtained by forming the inorganic layer on the base layer. In addition, as shown in Examples 1, 9, and 10, higher gas barrier properties can be obtained by using silicon nitride for the inorganic layer.

Furthermore, since the thickness of the inorganic layer in Example 4 is thicker than that in other examples falling within the most preferred range, the adhesiveness of the protective layer after the exposure to an environment with a high temperature and a high humidity is slightly lower than that in other examples, but there is no problem in practical use. In Example 6, since the plasma treatment strength of the resin film serving as the protective layer is lower than that in the other examples, the adhesiveness of the protective layer is slightly lower than that in the other examples, but there is no problem in practical use.

In contrast, in Comparative Example 1 in which the resin film serving as the protective layer was not subjected to a plasma treatment, the adhesiveness of the protective layer was extremely low.

In addition, in Comparative Example 2 in which the protective layer was adhered to the inorganic layer using an adhesive and Comparative Example 3 in which a self-pressure sensitive adhesive resin film that was not plasma-treated was used had low adhesiveness of the protective layer and a significant decrease in the adhesiveness of the protective layer after the exposure to an environment with a high temperature and a high humidity. Further, in both the cases, the total light transmittance is low.

In addition, in Comparative Examples, the reduction in the gas barrier properties after being exposed to an environment with a high temperature and a high humidity is significant. This is considered to be caused by a fact that the protective layer is partially peeled due to a decrease in the adhesiveness of the protective layer after the exposure to an environment with a high temperature and a high humidity, and as a result, the protective layer does not function sufficiently and the inorganic layer is damaged.

From the results, the effect of the present invention is apparent.

The functional film of the embodiment of the present invention can be suitably used as a sealing material for a solar cell and the like.

### EXPLANATION OF REFERENCES

10, 10A: functional film
10R: functional film roll
12: support
12R, 12aR: support roll
14: base layer
16: inorganic layer
18: protective layer
18F: resin film
18FR: resin film roll
40: organic film deposition apparatus
42: coating part
46, 46a, 46b: drying part
48: light irradiation part
50, 92: rotational shaft
52, 108: winding shaft
60: inorganic film deposition apparatus
62: partition wall
64: supply/winding chamber
68: film deposition chamber
70: drum
72: vacuum chamber
74, 76: vacuum exhausting unit
80: plasma treating unit
82, 114: shower electrode
84, 116: high frequency power supply
86, 118: gas supply unit
94a to 94c, 106a to 106c: pass roller
100A: first film deposition unit
100B: second film deposition unit
102: drum
114: shower electrode
116: high frequency power supply
118: gas supply unit

What is claimed is:

1. A functional film comprising:
a support;
an inorganic layer; and
a protective layer consisting of a resin film,
wherein the inorganic layer and the protective layer are directly joined to each other,
in a case where a maximum peak in a range of 2,800 to 2,900 cm⁻¹ is defined as a peak A and a maximum peak in a range of 2,900 to 3,000 cm⁻¹ is defined as a peak B in an infrared absorption spectrum, and an intensity ratio obtained by dividing an intensity of the peak B by an intensity of the peak A is defined as B/A,
the intensity ratio B/A in a surface of the protective layer on the inorganic layer side is 1.04 times or more the intensity ratio B/A in a surface of the protective layer on an opposite side to the inorganic layer.

2. The functional film according to claim 1,
wherein the inorganic layer has an inorganic compound containing silicon as a main component.

3. The functional film according to claim 2,
wherein the inorganic layer contains any one of silicon nitride, silicon oxide, or silicon oxynitride as a main component.

4. The functional film according to claim 1,
wherein a thickness of the inorganic layer is 50 nm or less.

5. The functional film according to claim 1,
wherein the functional film has a base layer between the support and the inorganic layer.

6. The functional film according to claim 1,
wherein a peeling strength between the protective layer and the inorganic layer is 2.5 N/25 mm or more.

7. The functional film according to claim 1,
wherein the protective layer contains polyethylene as a main component.

8. A method for producing a functional film, comprising:
an inorganic layer forming step of forming an inorganic layer on a support by a gas phase film deposition method under reduced pressure,
a treating step of plasma-treating one surface of a resin film under reduced pressure; and
a bonding step of making the inorganic layer and the plasma-treated surface of the resin film face each other while maintaining the reduced pressure to bond the inorganic layer to the resin film.

9. The method for producing a functional film according to claim 8,
wherein in the bonding step, a temperature of the resin film at the time of bonding the inorganic layer to the resin film is 80° C. or lower.

10. The method for producing a functional film according to claim 8,
wherein the formation of the inorganic layer in the inorganic layer forming step is performed by plasma CVD.

11. The method for producing a functional film according to claim 8,
wherein it is the inorganic layer that first comes into contact with the resin film after the formation of the inorganic layer in the inorganic layer forming step.

12. The method for producing a functional film according to claim 8,
wherein the support is a long support, and the inorganic layer forming step and the bonding step are performed while the long support is transported in a longitudinal direction.

13. The method for producing a functional film according to any claim 8,
wherein the resin film is a long resin film, and the treating step is performed while the long resin film is transported in a longitudinal direction.

14. The method for producing a functional film according to claim 8,
wherein a base layer forming step of forming a base layer on a surface of the support is performed before the inorganic layer forming step.
